(19) United States
(12) Patent Application Publication
(10) Pub. No.: US 2006/0071243 A1
(43) Pub. Date: Apr. 6, 2006

(54) THIN FILM TRANSISTOR ARRAY SUBSTRATE AND MANUFACTURING METHOD THEREOF

(76) Inventors: Han-Tung Hsu, Taoyuan County (TW); Wen-Hsiung Liu, Pintung County (TW); Chien-Kuo He, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,677

(22) Filed: Sep. 30, 2004

(51) Int. Cl. H01L 27/148

(52) U.S. Cl. 257/223

(57) ABSTRACT

A thin film transistor array substrate and manufacturing method thereof are provided. A shielding layer is formed between lead lines in a peripheral region of the substrate. The shielding layer and a gate layer may be formed simultaneously so that the light leakage between lead lines connected to a source/drain layer is reduced. Alternatively, the shielding layer and the source/drain layer may be formed simultaneously so that the light leakage between lead lines connected to a gate layer is reduced. Furthermore, a common voltage may be applied to the shielding layer so that signal interference between lead lines is reduced. Moreover, in an electrical inspection of the thin film transistor array, any short circuit between the lead lines and the shielding layer can be determined.

### BACKGROUND OF THE INVENTION

1. Field of the Invention

The present invention relates to a display panel and manufacturing method thereof. More particularly, the present invention relates to a thin film transistor array substrate and manufacturing method thereof.

2. Description of the Related Art

With the increase in computing power and the rapid development of Internet and multimedia technologies, most image data are transmitted in digital format rather than analogue format. To match the life style of modern people, video or image devices have been developed to be small and compact. In the past, conventional cathode ray tubes (CRT) used to be the dominant display devices because their high display quality and a low cost features. However, with the recent campaign for protecting the environmental, its bulkiness, high power consumption and high radiation makes it less desirable paving a way to develop display devices that are small, compact and energy-saving and low radiations.

In recent years, with great advance in the technique of fabricating electrical-optical and semiconductor devices, flat panel displays, such as a liquid crystal displays (LCD), have developed. Due to the advantageous features provided by the LCD, namely, a low operating voltage, free of harmful radiation, light weight and small and compact size, liquid crystal displays (LCD) have gradually replaced the conventional CRT and has become the mainstream display products.

FIG. 1 is a schematic cross-sectional view of a conventional liquid crystal display module. To simplify the drawing, only the components necessary for the explanation are shown in FIG. 1. The liquid crystal display module shown in FIG. 1 comprises a thin film transistor array substrate 110, a color filter substrate 120 including a black matrix layer 122 thereon, a seal 130, a liquid crystal layer 140, polarizing plates 152, 154 and an external frame 160. The seal 130 is disposed between the color filter substrate 120 and the thin film transistor array substrate 110 for sealing the color filter substrate 120 and the thin film transistor array substrate 110. The liquid crystal layer 140 is disposed within the space bounded by the color filter substrate 120, the thin film transistor array substrate 110 and the seal 130. Furthermore, the polarizing plates 152, 154 are disposed on the exterior surface of the thin film transistor array substrate 110 and the color filter substrate 120 respectively. The outer frame 160 is disposed on the polarizing plate 152. In addition, the thin film transistor array substrate 110 can be divided into a pixel region 110a and a peripheral region 110b. The peripheral region 110b has a plurality of lead lines 112 therein for connecting pixels in the pixel region 110a and peripheral circuits in the peripheral region 110b.

The conventional method of filling the liquid crystal layer 140 includes forming a sealed space between the thin film transistor array substrate 110 and the color filter substrate 120 using the seal 130. Thereafter, liquid crystal is slowly injected into the aforementioned sealed space through the capillary effect under the atmospheric pressure. Because the injection process is rather slow, it is unsuitable for fabricating large size liquid crystal display panel. To increase the speed of the fabrication process, a liquid crystal drop filling (ODF) method for fabricating LCD panel has been developed. In the ODF method, the seal 130 is formed on the thin film transistor array substrate 110 or the color filter substrate 120. Liquid crystal is dropped into an area enclosed by the seal 130. Thereafter, the thin film transistor array substrate 110 and the color filter substrate 120 are sealed together. Finally, the seal 130 is irradiated with ultraviolet light to cure the seal 130 and bond the thin film transistor array substrate 110 and the color filter substrate 120 together.

To prevent the incompletely irradiated seal material from contaminating the liquid crystal 140, the black matrix layer 122 on the color filter substrate 100 is shrunk towards the center of the panel by a short distance. However, with the black matrix layer 122 slightly contracted, a light-leaking area 170 is formed between the black matrix layer 122 and the seal 130. In addition, there is no shade in the area between the lead lines 112 within the peripheral region 110b. Hence, light 180 emitted from the back light module may pass through the areas between the lead lines 112 and produce a vertical or slant light beam at the junction between the outer frame 160 and the thin film transistor array substrate 110.

### SUMMARY OF THE INVENTION

Accordingly, the present invention is directed to a thin film transistor array substrate and a fabricating method thereof capable of resolving the problem of light leakage from a peripheral region.

The present invention provides a thin film transistor array substrate is provided. The thin film transistor array substrate comprises a pixel region and a peripheral region surrounding the pixel region. The thin film transistor array substrate comprises a transparent substrate, a thin film transistor array, a plurality of first lead lines, a plurality of second lead lines and a first shielding layer. The thin film transistor array is disposed on the transparent substrate within the pixel region. The thin film transistor array comprises at least a first conductive layer and a second conductive layer. The first lead lines are disposed over the transparent substrate within the peripheral region. The first lead lines and the first conductive layer are the same film layer. Similarly, the second lead lines are disposed over the transparent substrate within the peripheral region. The second lead lines and the second conductive layer are the same film layer. The first shielding layer is disposed over the transparent substrate within the peripheral region, and the first shielding layer and the second conductive layer are the same film layer. Especially, the first shielding layer is disposed covering the gaps between neighboring first lead lines.

The present invention is also directed to a method of fabricating a thin film transistor array substrate. A transparent substrate having a pixel region and a peripheral region is provided. A patterned gate layer is formed in the pixel region, and a plurality of first lead lines and a plurality of first bonding pads connected to the first lead lines are formed in the peripheral region simultaneously. An insulating layer is formed over the transparent substrate to cover the gate layer and the first lead lines. A patterned channel layer is formed over the insulating layer above the gate layer. A patterned source/drain layer is formed over the channel layer, and a plurality of second lead lines and a plurality of second bonding pads connected to the lead lines are formed in the peripheral region. Particularly, the process of forming the source/drain layer further includes forming a first shielding layer covering the gaps between neighboring first lead lines.

The present invention is also directed to an alternative method of fabricating a thin film transistor array substrate. First, a transparent substrate having a pixel region and a peripheral region is provided. Thereafter, a patterned gate layer is formed in the pixel region and a plurality of first lead lines and a plurality of first bonding pads connected to various first lead lines are formed in the peripheral region. An insulating layer is formed over the transparent substrate to cover the gate layer and the first lead lines. A patterned channel layer is formed over the insulating layer above the gate layer. A patterned source/drain layer is formed over the channel layer and a plurality of second lead lines and a plurality of second bonding pads connected to various lead lines are formed in the peripheral region. Particularly, the process of forming the gate layer further includes forming a shielding layer in a location underneath the subsequently formed gaps between neighboring second lead lines.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional liquid crystal display module.

FIG. 2 is a top view of a thin film transistor array according to an embodiment of the present invention.

FIG. 3 is a cross-sectional view showing a local section of a thin film transistor array according to an embodiment of the present invention.

FIG. 4 is a magnified cross-sectional view showing a structural layout of gate lines in the peripheral region according to an embodiment of the present invention.

FIG. 5 is a magnified cross-sectional view showing a structural layout of source lines in the peripheral region according to an embodiment of the present invention.

FIGS. 6 and 7 are top views showing first bonding pads and second bonding pads according to another embodiment of the present invention.

FIGS. 8A through 8E are schematic cross-sectional views showing the steps of fabricating a thin film transistor array substrate according to an embodiment of the present invention.

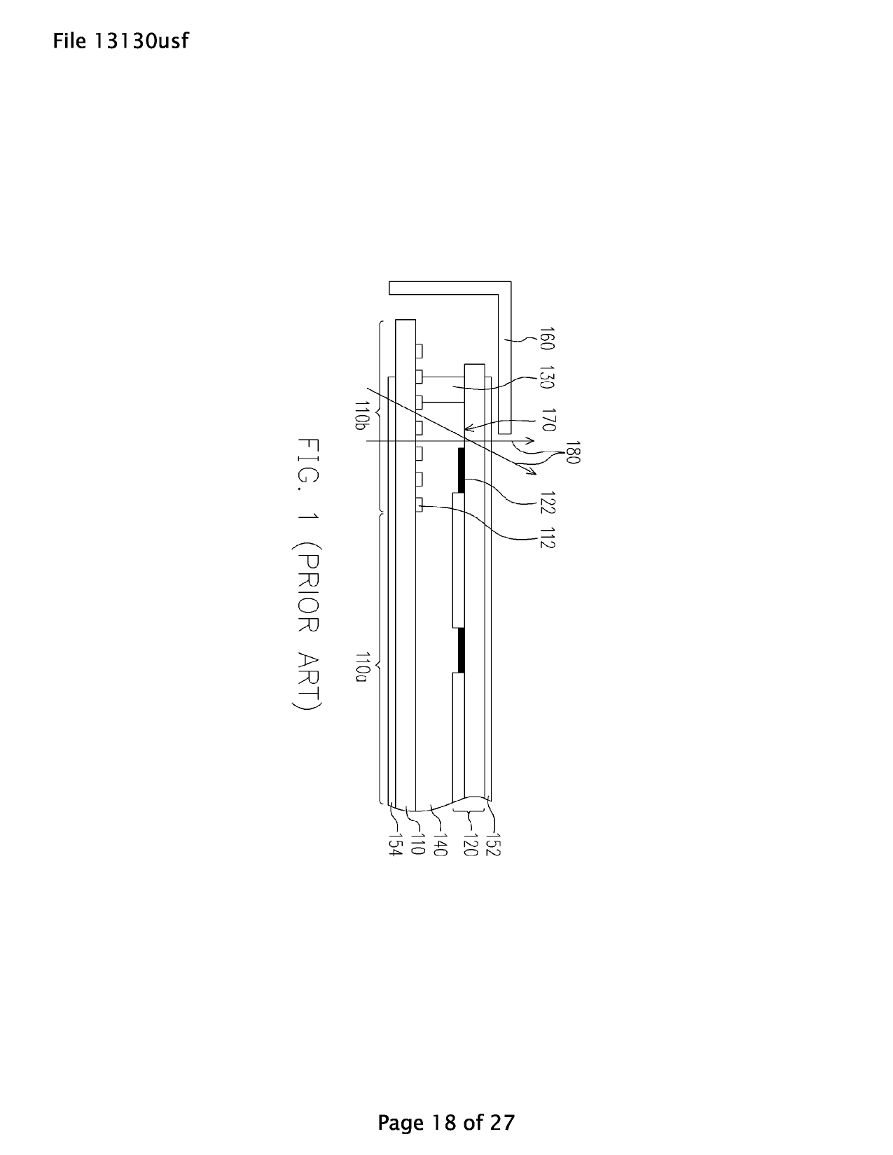

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

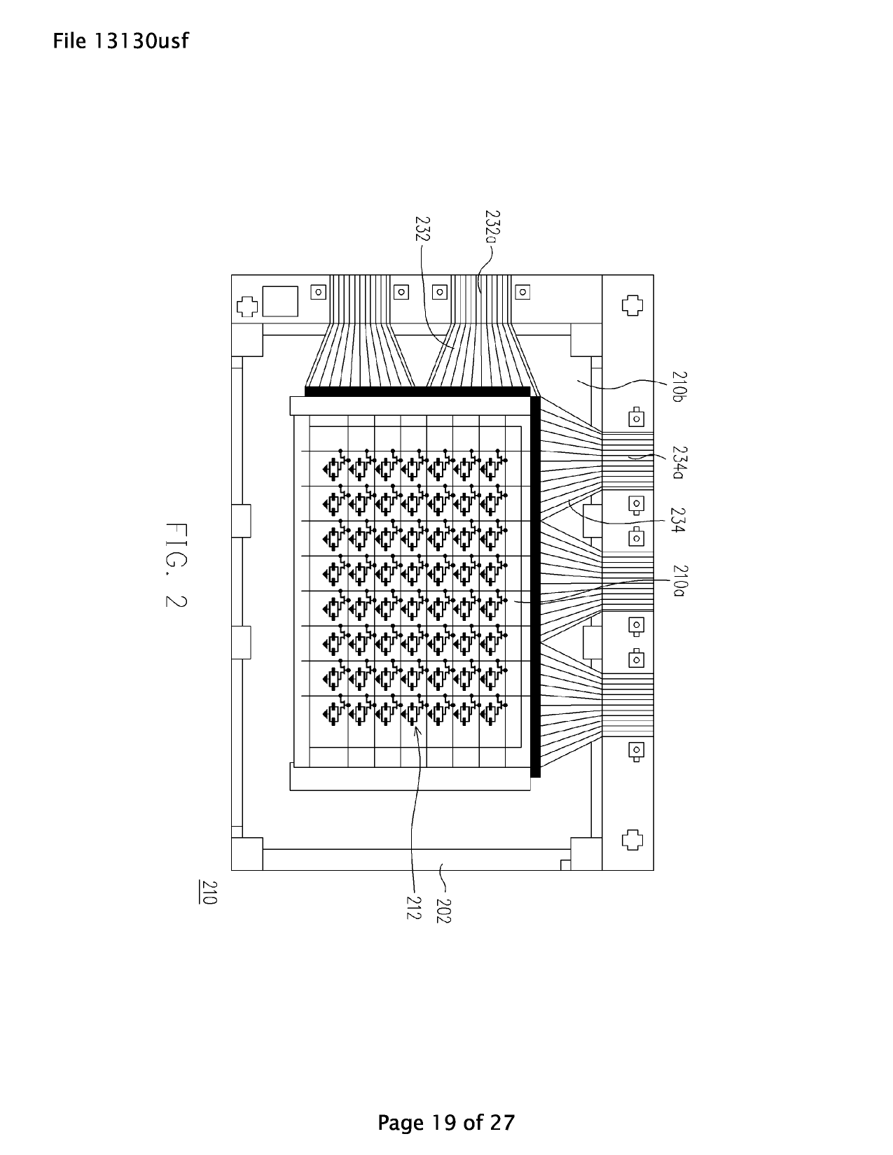

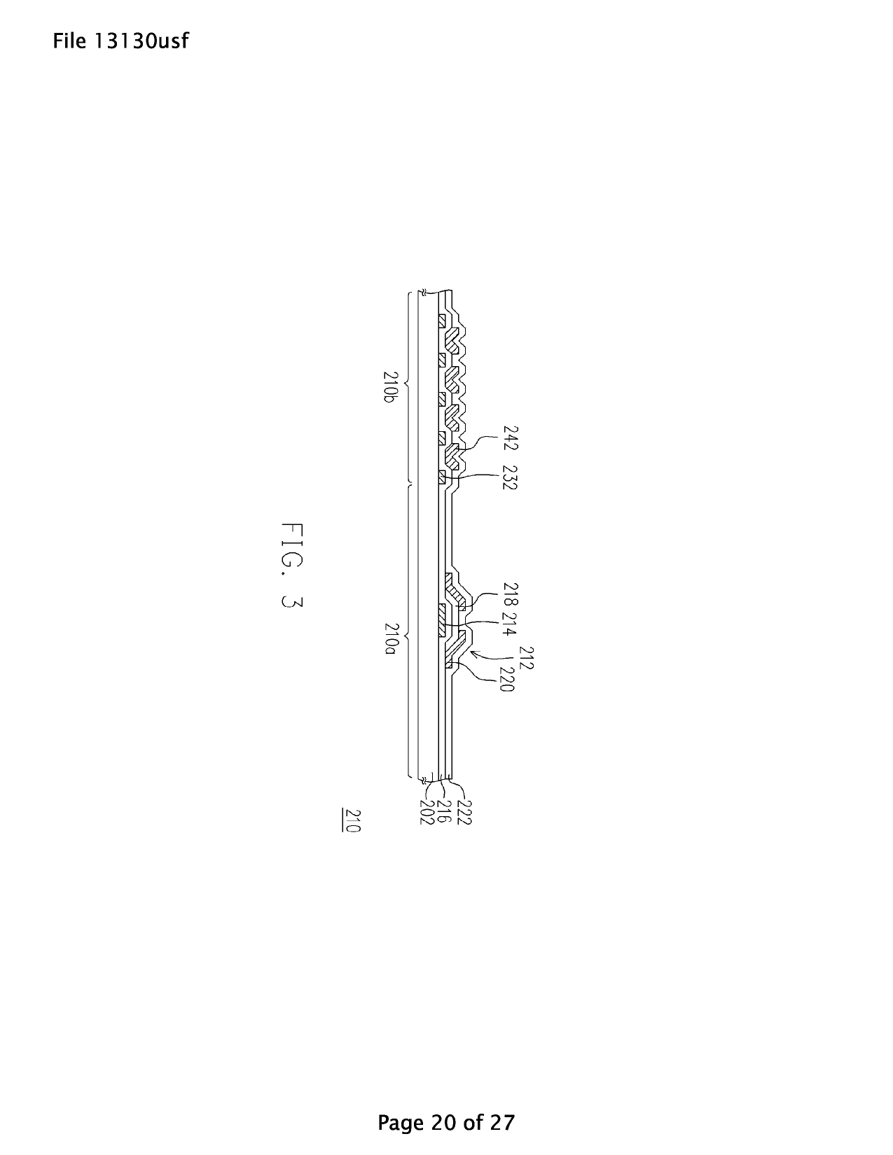

FIG. 2 is a top view of a thin film transistor array according to an embodiment of the present invention. FIG. 3 is a cross-sectional view showing a local section of a thin film transistor array according to an embodiment of the present invention. As shown in FIG. 2, the thin film transistor array substrate 210 includes a pixel region 210a and a peripheral region 210b surrounding the pixel region 210a. A thin film transistor array 212 comprising a plurality of thin film transistors and a plurality of pixel electrodes (not shown) are disposed on a transparent substrate 202 within the pixel region 210a. A plurality of lead lines such as gate lines 232 or source lines 234 linking with the thin film transistor array is disposed on the transparent substrate 202 within the peripheral region 210b. In addition, one end of each gate line 232 and the source line 234 are connected to a first bonding pad 232a and a second bonding pad 234a respectively for connecting to external circuits. As shown in FIG. 3, the thin film transistor array 212 comprises a gate layer 214, an insulating layer 216, a channel layer 218, a source/drain layer 220 and a passivation layer 222, for example. The gate lines 232 and the gate layer 214 are comprised of the same film layer.

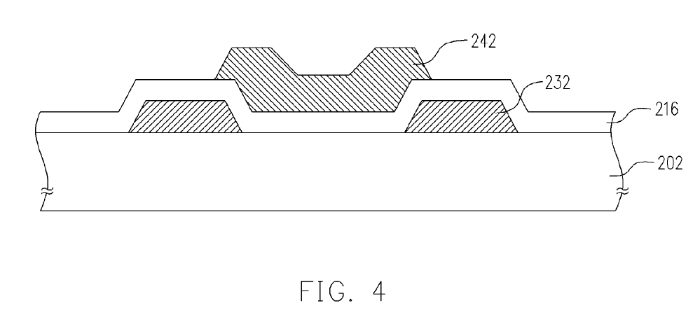

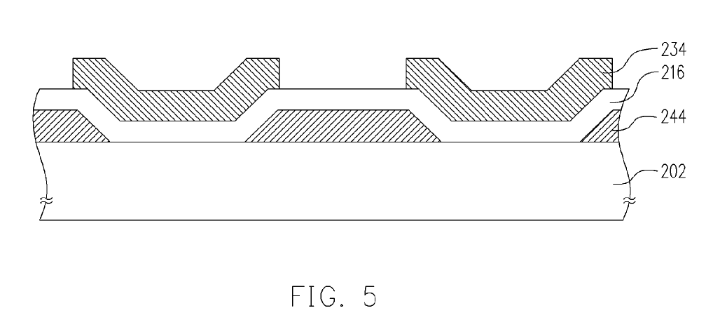

As shown in FIG. 3, to reduce light leaking from the gaps between the gate lines 232 in the peripheral region 210b, a patterned first shielding layer 242 is formed over the gate lines 232 in the peripheral region 210b. The first shielding layer 242 at least covers the gaps between neighboring gate lines 232. Furthermore, the first shielding layer 242 and the source/drain layer 220 may be fabricated together in the same process. FIG. 4 is a magnified cross-sectional view showing the structural layout of the gate line 232 and the first shielding layer 242 according to an embodiment of the present invention. Similarly, the gaps between the source lines 234 in the peripheral region 210b may be covered with another shielding layer as shown in FIG. 5. FIG. 5 is a magnified cross-sectional view showing a structural layout of the source line 234 in the peripheral region 210b according to an embodiment of the present invention. As shown in FIG. 5, a patterned second shielding layer 244 is formed under the source line 234 in a location between the gaps of neighboring source lines 234. The second shielding layer 244 and the gate layer 214 may be fabricated together in the same process, for example. In an embodiment of the present invention, at least one of the first shielding layer 242 and the second shielding layer 244 are formed over the substrate 202. In another embodiment, both the first shielding layer 242 and the second shielding layer 244 are formed over the substrate 202.

The thin film transistor array substrate 210, according to an embodiment of the present invention, utilizes the first shielding layer 242 and the second shielding layer 244 to cover the gaps between neighboring gate lines 232 or neighboring source lines 234. The first shielding layer 242 and the second shielding layer 244 can be patterned simultaneously so that they are formed in the gaps between neighboring gate lines 232 or neighboring source lines 234. Hence, compared with other designs having a shielding layer that covers the lead lines completely, resistance-capacitance (RC) delay of the present invention is significantly reduced. Obviously, in the events of errors during the fabrication process, the shielding layer (the first shielding layer 242 and the second shielding layer 244) and the light-leaking region (the gaps between neighboring gate lines 232 and neighboring source lines 234) may partially overlap.

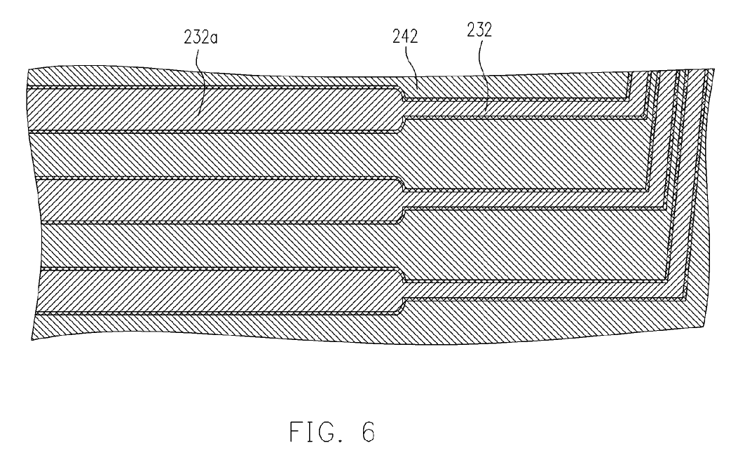

In another embodiment of the present invention, the first shielding layer 242 and the second shielding layer 244 may extend into the first bonding pads 242a and the second bonding pads 244a to reduce light leakage at an angle. FIGS. 6 and 7 are top views showing first bonding pads and second bonding pads according to another embodiment of the present invention. In FIG. 6, the first shielding layer 242 extended to cover the gaps between neighboring first bonding pads 232a aside from the gaps between neighboring gate lines 232. In FIG. 7, the second shielding layer 244 extended to cover the gaps between neighboring second bonding pads 234a aside from the gaps between neighboring source lines 234.

Furthermore, one other aspect of the present invention is that a common voltage may be applied to the first shielding layer 242 and the second shielding layer 244. The application of a common voltage reduces signal interference between lead lines (the gate lines 232 or the source lines 234) and thereby reduces the deterioration of pixel quality. Moreover, the voltage also facilitates in the determination of any short circuit between the lead lines and the shielding layer of the thin film transistor array by performing an electrical inspection testing process.

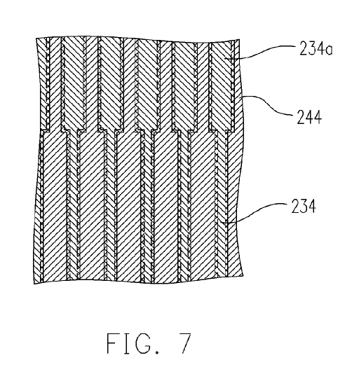

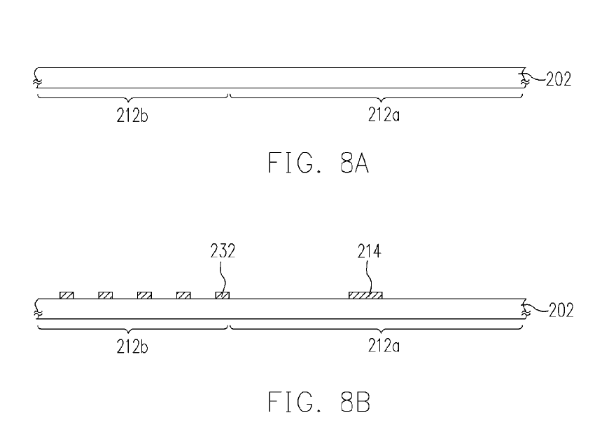

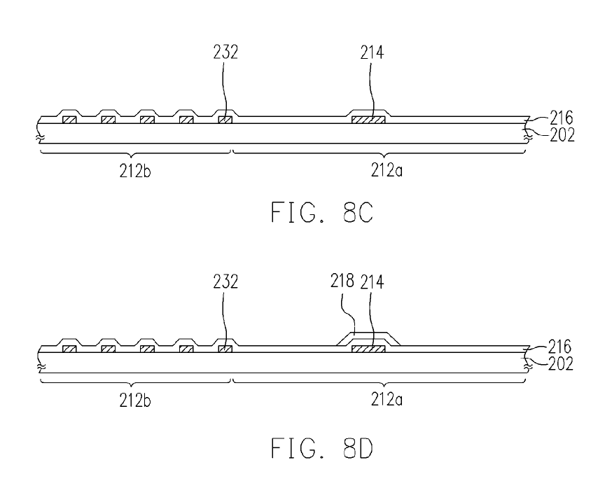

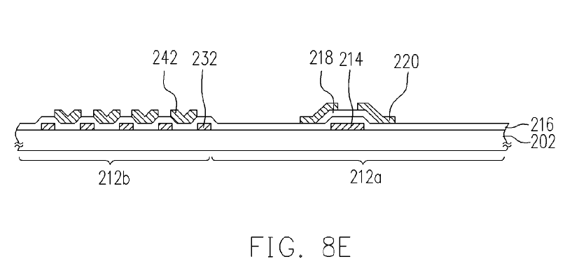

FIGS. 8E through 8E are schematic cross-sectional views showing the steps for fabricating a thin film transistor array substrate according to an embodiment of the present invention. As shown in FIG. 8A, a transparent substrate 202 having a pixel region 212a and a peripheral region 212b thereon is provided. The transparent substrate 202 is a glass substrate or a plastic substrate, for example.

As shown in FIG. 8B, a metallic layer (not shown) is formed in the pixel region 212a. The metallic layer is patterned to form a patterned gate layer 214 within the pixel region 212a and a plurality of gate lines 232 and a plurality of first bonding pads (not shown) connected to the gate lines 232 within the peripheral region 212b. The metallic layer is formed in a sputtering operation, for example.

As shown in FIG. 8C, an insulating layer 216 is formed over the transparent substrate 202 to cover the gate layer 214 in the pixel region 212a and the gate lines 232 in the peripheral region 212b. The insulating layer 216 is a silicon nitride layer or a silicon oxide layer formed, for example, by performing a plasma-enhanced chemical vapor deposition process.

As shown in FIG. 8D, a channel layer (not shown) is formed over the insulating layer 216. The channel layer is patterned to form a channel layer 218 over the insulating layer 216 above the gate 212. The channel layer 218 is fabricated using an amorphous silicon (a-Si) layer, for example.

As shown in FIG. 8E, another metallic layer (not shown) is formed over the transparent substrate 202. The metallic layer is etched to form a patterned source/drain layer 220 within the pixel region 212a, and a plurality of source lines 234 and a plurality of second bonding pads (not shown) connected to the source lines 234 within the peripheral region 212b. Furthermore, a first shielding layer 242 is formed covering the gaps between neighboring gate lines 232. According to one embodiment of the present invention, the first shielding layer 242 may extend into regions over the gaps between neighboring first bonding pads.

Obviously, other protective layers such as a passivation layer 222 (as shown in FIG. 3), an electrode film (not shown) and an orientation film (not shown) may also be fabricated over the substrate 202. Since the processes of fabricating the aforementioned films are well-known to those skilled in the art, detailed description thereof are omitted herein.

In one embodiment of the present invention, a second shielding layer 244 (as shown in FIGS. 5 and 7) may be patterned in the process of fabricating the gate layer 214. The second shielding layer 244 is formed underneath the gaps between subsequently formed neighboring source lines 234. According to one embodiment of the invention, the second shielding layer 244 may extend into regions underneath the gaps between subsequently formed neighboring second bonding pads.

In summary, in the thin film transistor array substrate and the fabricating method thereof according to the present invention, a shielding layer is formed within the peripheral region in locations where light might possibly leak out. The shielding layer formed together with the gate layer is able to reduce any light leakage from the gaps between the source lines and the bonding pads. On the other hand, the shielding layer formed together with the source/drain layer is able to reduce light leakage from the gaps between the gate lines and the bonding pads. Obviously, the shielding layer may be fabricated to cover the gaps between the gate lines or the source lines alone or some other areas within the peripheral region where the probability of light leakage from that location is high. It should be noted that the shielding layer is formed together with the gate layer or the source/drain layer of the thin film transistor in the above embodiments. However, the shielding layer is not limited to be formed together with the gate layer or the source/drain layer. The shielding layer may also be formed not together with the gate layer or the source/drain layer. The shielding layer can be constituted of metal, black resin or other suitable shielding materials.

In conclusion, the thin film transistor array substrate and manufacturing method thereof has at least the following characteristics and advantages:

1. The shielding layer is patterned to reduce the amount of overlap between the shielding layer and the lead line so that resistance-capacitance delay between the shielding layer and the lead lines is greatly reduced.

2. The shielding layer may extend into the gaps between bonding pads to reduce light leakage from the substrate at an angle.

3. A common voltage can be applied to the shielding layer to reduce signal interference between neighboring lead lines and improve display quality.

4. The application of a common voltage to the shielding layer also facilitate the determination of any short circuit between the lead lines and the shielding layer in a post fabrication electrical inspection of the thin film transistor array.

5. The shielding layer is formed together with the thin film transistor array so that no need additional process steps are required without impacting the processing time and the production cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor array substrate having a pixel region and a peripheral region surrounding the pixel region, comprising:
a transparent substrate;
a thin film transistor array, disposed over the transparent substrate within the pixel region, wherein the thin film transistor array at least comprises a first conductive layer and a second conductive layer;
a plurality of first lead lines, disposed over the transparent substrate within the peripheral region, wherein both the first lead lines and the first conductive layer belong to a same film layer;
a plurality of second lead lines, disposed over the transparent substrate within the peripheral region, wherein both the second lead lines and the second conductive layer belong to a same film layer; and
a first shielding layer, disposed over the transparent substrate within the peripheral region to cover the gaps between neighboring first lead lines, and both the first shielding layer and the second conductive layer belong to a same film layer.

2. The thin film transistor array substrate of claim 1, further comprising a second shielding layer disposed over the transparent substrate within the peripheral region to cover the gaps between neighboring second lead lines, and both the second shielding layer and the first conductive layer belong to the same film layer.

3. The thin film transistor array substrate of claim 2, wherein a common voltage is applied to the first shielding layer.

4. The thin film transistor array substrate of claim 3, wherein a common voltage is applied to the second shielding layer.

5. The thin film transistor array substrate of claim 1, wherein a common voltage is applied to the first shielding layer.

6. The thin film transistor array substrate of claim 1, wherein the first conductive layer comprises a gate layer, and the second conductive layer comprises a source/drain layer.

7. The thin film transistor array substrate of claim 1, wherein the first conductive layer comprises a source/drain layer, and the second conductive layer comprises a gate layer.

8. A thin film transistor array substrate having a pixel region and a peripheral region surrounding the pixel region, comprising:
a transparent substrate;
a thin film transistor array, disposed over the transparent substrate within the pixel region, wherein the thin film transistor array at least comprises a first conductive layer and a second conductive layer;
a plurality of first lead lines, disposed over the transparent substrate within the peripheral region, wherein the first lead lines and the first conductive layer belong to a same film layer;
a plurality of first bonding pads, disposed over the transparent substrate within the peripheral region and connected to the first lead lines, wherein the first bonding pads and the first conductive layer belongs to the same film layer;
a plurality of second lead lines, disposed on the transparent substrate within the peripheral region, wherein the second lead lines and the second conductive layer belong to a same film layer;
a plurality of second bonding pads, disposed on the transparent substrate within the peripheral region and connected to the second lead lines, wherein the second bonding pads and the second conductive layer belong to a same film layer; and
a first shielding layer, disposed on the transparent substrate within the peripheral region to cover the gaps between neighboring first lead lines, wherein the first shielding layer and the second conductive layer belong to a same film layer.

9. The thin film transistor array substrate of claim 8, further comprising a second shielding layer disposed over the transparent substrate within the peripheral region to cover the gaps between neighboring second lead lines, and the second shielding layer and the first conductive layer belong to the same film layer.

10. The thin film transistor array substrate of claim 9, wherein a common voltage is applied to the first shielding layer.

11. The thin film transistor array substrate of claim 10, wherein a common voltage is applied to the second shielding layer.

12. The thin film transistor array substrate of claim 8, wherein a common voltage is applied to the first shielding layer.

13. The thin film transistor array substrate of claim 8, wherein the first conductive layer comprises a gate layer, and the second conductive layer comprises a source/drain layer.

14. The thin film transistor array substrate of claim 8, wherein the first conductive layer comprises a source/drain layer, and the second conductive layer comprises a gate layer.

15. A method of fabricating a thin film transistor array substrate, comprising the steps of:
providing a transparent substrate, wherein the transparent substrate comprises a pixel region and a peripheral region;
forming a patterned gate layer over the transparent substrate within the pixel region and a plurality of first lead lines and a plurality of first bonding pads connected to the first lead lines on the transparent substrate within the peripheral region;
forming an insulating layer over the transparent substrate covering the gate layer and the first lead lines;
forming a patterned channel layer over the insulating layer above the gate layer; and
forming a patterned source/drain layer over the channel layer and a plurality of second lead lines and a plurality of second bonding pads connected to the second lead lines over the transparent substrate within the peripheral region;
wherein a first shielding layer formed to cover the gaps between neighboring first lead lines.

16. The method of fabricating a thin film transistor array substrate of claim 15, wherein the first shielding layer further extends to cover the gaps between neighboring first bonding pads.

17. The method of fabricating a thin film transistor array substrate of claim 15, wherein the step of forming the gate layer further comprises a step of forming a second shielding layer under the gaps between subsequently formed neighboring second lead lines.

18. The method of fabricating the thin film transistor array substrate of claim 17, wherein the step of forming the second shielding layer further comprises a step of extending the second shielding layer into an region under the gaps between subsequently formed neighboring second bonding pads.

19. A method of fabricating a thin film transistor array substrate, comprising the steps of:
providing a transparent substrate, wherein the transparent substrate includes a pixel region and a peripheral region;
forming a patterned gate layer over the transparent substrate within the pixel region and a plurality of first lead lines and a plurality of first bonding pads connected to the first lead lines on the transparent substrate within the peripheral region;
forming an insulating layer over the transparent substrate covering the gate layer and the first lead lines;
forming a patterned channel layer over the insulating layer above the gate layer; and
forming a patterned source/drain layer over the channel layer and a plurality of second lead lines and a plurality of second bonding pads connected to the second lead lines over the transparent substrate within the peripheral region;
wherein a shielding layer is formed under the gaps between subsequently formed neighboring second lead lines.

20. The method of fabricating the thin film transistor array substrate of claim 19, wherein the step of forming the shielding layer further comprises a step of extending the shielding layer into an region under the gaps between subsequently formed neighboring second bonding pads.
